(19) United States
(12) Patent Application Publication
(10) Pub. No.: US 2024/0244893 A1
(43) Pub. Date: Jul. 18, 2024

(54) Display Device

(71) Applicant: LG Display Co., Ltd., Seoul (KR)

(72) Inventors: Moonsung Kil, Paju-si (KR); YongCheol Kim, Gimpo-si (KR); Mi-Na Kim, Paju-si (KR)

(21) Appl. No.: 18/522,699

(22) Filed: Nov. 29, 2023

(30) Foreign Application Priority Data
Jan. 18, 2023 (KR) 10-2023-0007392

(51) Int. Cl. H10K 59/122; H10K 59/35; H10K 59/80

(52) U.S. Cl. CPC H10K 59/122; H10K 59/351; H10K 59/353; H10K 59/80515; H10K 59/80518; H10K 59/873

(57) ABSTRACT

A display device according to an exemplary embodiment of the present disclosure includes a planarization layer disposed above a substrate, a first bank disposed on the planarization layer, an anode disposed on the planarization layer and on a side surface of the first bank, a second bank covering a portion of the anode and the first bank and disposed above the first bank and the anode, a doping layer disposed on a top surface and a side portion of the second bank, an organic layer which is disposed on the doping layer and the anode, a cathode disposed on the organic layer, and an encapsulating unit disposed above the cathode. By doing this, the reflectance is reduced and the damage of the light emitting diode is suppressed.

### CROSS-REFERENCE TO RELATED APPLICATION

This application claims the benefit of Republic of Korea Patent Application No. 10-2023-0007392 filed on Jan. 18, 2023, which is hereby incorporated by reference in its entirety.

### BACKGROUND

### Field

The present disclosure relates to a display device.

### Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, an electroluminescent display device is a self-emitting display device so that a separate light source is not necessary, which is different from a liquid crystal display device. Therefore, the electroluminescent display device may be manufactured to have a light weight and a small thickness. Further, since the electroluminescent display device is driven at a low voltage so that it is advantageous not only in terms of power consumption, but also in terms of color implementation, a response speed, a viewing angle, a contrast ratio (CR). Therefore, it is expected to be utilized in various fields.

In the meantime, light emitted from an emission layer of the electroluminescent display device passes through various components of the electroluminescent display device to be released to the outside of the electroluminescent display device. However, some of light emitted from the emission layer is trapped in the electroluminescent display device without being released to the outside of the electroluminescent display device so that the light extraction efficiency of the electroluminescent display device becomes an issue.

### SUMMARY

An object to be achieved by the present disclosure is to provide a display device which improves a light extraction efficiency.

Another object to be achieved by the present disclosure is to provide a display device which reduces a reflectance.

Still another object to be achieved by the present disclosure is to provide a display device which suppresses a device defect due to anions generated in a black bank.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device may include a planarization layer, a first bank disposed on the planarization layer, an anode disposed on the planarization layer and on a side surface of the first bank, a second bank covering a portion of the anode and the first bank and disposed above the first bank and the anode, a doping layer disposed on a top surface and a side portion of the second bank, an organic layer which is disposed on the doping layer and the anode, a cathode disposed on the organic layer and an encapsulation unit disposed above the cathode.

According to another aspect of the present disclosure, a display device may include a planarization layer disposed above a substrate, a first bank disposed on the planarization layer, an anode disposed on the planarization layer and on a side surface of the first bank, a second bank covering a portion of the anode and the first bank and disposed above the first bank and the anode, an organic layer disposed on the second bank and the anode, a cathode disposed on the organic layer and an encapsulating unit disposed above the cathode. The second bank may include dopants, such as a p-type impurity with a positive charge.

Other detailed matters of the exemplary embodiments are included in the detailed description and the drawings.

According to the present disclosure, the light extraction efficiency of the display device may be improved using a side mirror type anode. Accordingly, the present disclosure may implement a low power.

According to the present disclosure, a black bank is disposed below a transparent bank to reduce the reflectance.

According to the present disclosure, a p-doping layer is added above the black bank or a dopant, such as a p-type impurity is injected into a transparent bank to suppress the device defect due to anions generated in the black bank.

According to the present disclosure, a display device includes a substrate, a planarization layer disposed on the substrate, a first subpixel and a second subpixel on the substrate, the second subpixel spaced apart from and positioned adjacent to the first subpixel, and each of the first subpixel and second subpixel including an anode electrode, the anode electrode including reflective material, at least a portion of an organic layer, and at least a part of a cathode electrode on the organic layer. The display device further including a first black bank between the first subpixel and the second subpixel, wherein the anode electrode extends to a side surface of the first black bank: and a doping layer disposed above the first black bank.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view schematically illustrating a configuration of a display device according to a first exemplary embodiment of the present disclosure:

FIG. 2 is a view schematically illustrating a display panel of FIG. 1, according to an embodiment of the present disclosure:

FIG. 3 is a perspective view illustrating a structure in which a touch panel is embedded in a display panel, according to an embodiment of the present disclosure;

FIG. 4 is a cross-sectional view taken along the line I-I′ of FIG. 2, according to an embodiment of the present disclosure:

FIG. 5 is a view illustrating a lamination structure of a light emitting diode of FIG. 4, according to an embodiment of the present disclosure:

FIG. 6 is a view illustrating a part of a cross-section of a display panel according to a second exemplary embodiment of the present disclosure:

FIG. 7 is a view illustrating a lamination structure of a light emitting diode of FIG. 6, according to an embodiment of the present disclosure:

FIG. 8 is a view illustrating a part of a cross-section of a display panel according to a third exemplary embodiment of the present disclosure:

FIG. 9 is a view illustrating a lamination structure of a light emitting diode of FIG. 8, according to an embodiment of the present disclosure:

FIG. 10 is a view illustrating a part of a cross-section of a display panel according to a fourth exemplary embodiment of the present disclosure:

FIG. 11 is a view illustrating a lamination structure of a light emitting diode of FIG. 10, according to an embodiment of the present disclosure;

FIGS. 12A to 12D are views illustrating a pixel structure according to exemplary embodiments of the present disclosure: and

FIG. 13 is a view illustrating a part of a cross-section of a display panel according to a fifth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

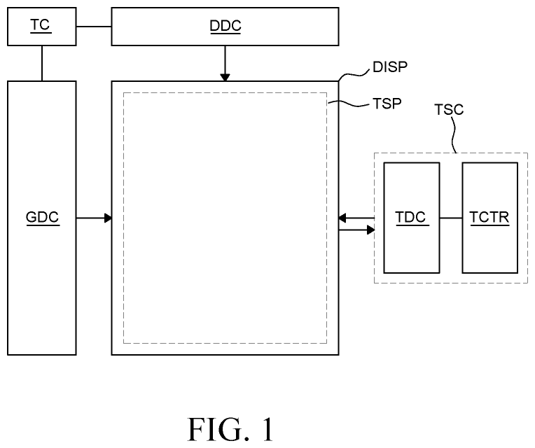

FIG. 1 is a view schematically illustrating a configuration of a display device according to a first exemplary embodiment of the present disclosure.

For example, FIG. 1 illustrates a schematic configuration of a display device in which a touch panel TSP according to a first exemplary embodiment of the present disclosure is embedded. However, the present disclosure is not limited thereto and a display device according to the exemplary embodiments of the present disclosure may not include a display panel.

Referring to FIG. 1, the display device according to the first exemplary embodiment of the present disclosure may provide both a function for displaying images and a function for sensing a touch.

In order to provide an image displaying function, the display device according to the first exemplary embodiment of the present disclosure may include a display panel DISP, a gate driving circuit GDC, a data driving circuit DDC, and a timing controller TC.

For example, in the display panel DISP, a plurality of data lines and a plurality of gate lines are disposed and a plurality of subpixels defined by the plurality of data lines and the plurality of gate lines may be disposed.

The data driving circuit DDC drives a plurality of data lines and the gate driving circuit GDC drives a plurality of gate lines, and the timing controller TC may control an operation of the data driving circuit DDC and the gate driving circuit GDC.

Each of the data driving circuit DDC, the gate driving circuit GDC, and the timing controller TC may be implemented by one or more individual components. In some cases, two or more of the data driving circuit DDC, the gate driving circuit GDC, and the timing controller TC may be implemented to be combined as one component. For example, the data driving circuit DDC and the timing controller TC may be implemented as one integrated chip (IC chip).

In order to provide a touch sensing function, the display device according to the first exemplary embodiment of the present disclosure may include a touch panel TSP and a touch sensing circuit TSC. The touch panel TSP includes a plurality of touch electrodes. The touch sensing circuit TSC supplies a touch driving signal to the touch panel TSP and detects a touch sensing signal from the touch panel TSP to sense the presence of a touch of a user or a touch position (touch coordinate) in the touch panel TSP based on the detected touch sensing signal.

For example, the touch sensing circuit TSC may include a touch driving circuit TDC, a touch controller TCTR, and the like. The touch driving circuit TDC supplies a touch driving signal to the touch panel TSP and detects a touch sensing signal from the touch panel TSP. The touch controller TCTR senses the presence of a touch of a user and/or a touch position in the touch panel TSP based on the touch sensing signal detected by the touch driving circuit TDC. The touch driving circuit TDC may include a first circuit part which supplies the touch driving signal to the touch panel TSP and a second circuit part which detects the touch sensing signal from the touch panel TSP.

For example, the touch driving circuit TDC and the touch controller TCTR may be implemented by separate components or in some cases, may be implemented to be combined as one component.

For example, each of the data driving circuit DDC, the gate driving circuit GDC, and the touch driving circuit TDC may be implemented by one or more integrated circuits. From the viewpoint of electrical connection with the display panel DISP, the circuits may be implemented by a chip on glass (COG) type, a chip on film (COF) type, a tape carrier package (TCP) type, or the like. Further, the gate driving circuit GDC may also be implemented by a gate in panel (GIP) type.

For example, each of circuit configurations DDC, GDC, and TC for display driving and circuit configurations TDC and TCTR for touch sensing may be implemented by one or more individual components. In some cases, one or more of circuit configurations DDC, GDC, and TC for display driving and one or more of circuit configurations TDC and TCTR for touch sensing are functionally integrated to be implemented by one or more components.

For example, the data driving circuit DDC and the touch driving circuit TDC may be implemented to be integrated in one or two or more integrated circuit chips. When the data driving circuit DDC and the touch driving circuit TDC are implemented to be integrated in two or more integrated circuit chips, each of two or more integrated circuit chips may have a data driving function and a touch driving function.

In the meantime, the display device according to the first exemplary embodiments of the present disclosure may be various types such as a light emitting display device or a liquid crystal display device. Hereinafter, for the convenience of description, a light emitting display device will be described as an example of the display device. That is, even though the display panel DISP may be various types such as a light emitting display panel or a liquid crystal display panel, in the following description, for the convenience of description, a light emitting display panel will be described as an example of the display panel DISP.

Further, in the meantime, as it will be described below, the touch panel TSP may include a plurality of touch electrodes which is applied with a touch driving signal or detects a touch sensing signal therefrom and a plurality of touch routing lines which connects the plurality of touch electrodes to the touch driving circuit TDC.

The touch panel TSP may be provided at the outside of the display panel DISP. For example, the touch panel TSP and the display panel DISP may be separately manufactured to be combined. Such a touch panel TSP is called an external type or an add-on type.

In contrast, the touch panel TSP may be embedded in the display panel DISP. For example, when the display panel DISP is manufactured, a touch sensor structure such as a plurality of touch electrodes and a plurality of touch routing lines which configure a touch panel TSP may be formed together with a plurality of electrodes and signal lines for display driving.

Further, the touch panel TSP may be formed directly above the encapsulation unit of the display panel DISP. For example, the touch insulating film and the touch electrodes are patterned above the encapsulation unit and the touch panel is connected to signal lines formed as electrodes for display driving to be driven. Hereinafter, for the convenience of description, an example that the touch panel TSP is formed directly above the encapsulation unit will be described.

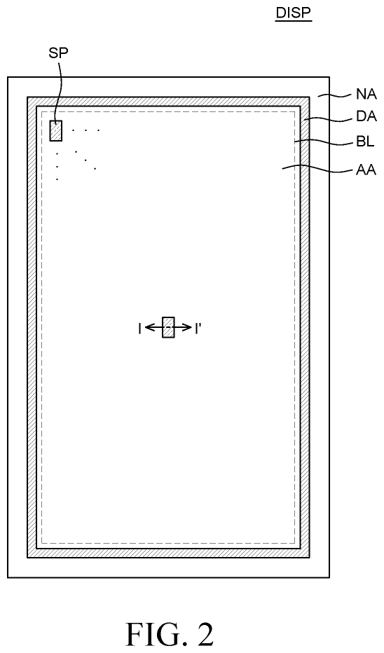

FIG. 2 is a view schematically illustrating a display panel of FIG. 1, according to an embodiment of the present disclosure.

Referring to FIG. 2, the display panel DISP may include an active area AA in which images are displayed and a non-active area NA which is an outer area of an outer boundary line BL of the active area AA.

In the active area AA of the display panel DISP, a plurality of subpixels SP for displaying images is disposed and various electrodes or signal lines for display driving are disposed.

Further, in the active area AA of the display panel DISP, a plurality of touch electrodes for touch sensing and a plurality of touch routing lines electrically connected thereto may be disposed. Accordingly, the display area AA may also be referred to as a touch sensing area which is capable of sensing the touch.

In the non-active area NA of the display panel DISP, link lines extending from various signal lines disposed in the active area AA or link lines which are electrically connected to various signal lines disposed in the active area AA, and pads which are electrically connected to the link lines may be disposed. The pads disposed in the non-active area NA may be bonded or electrically connected with the display driving circuit.

Further, in the non-active area NA of the display panel DISP, link lines extending from a plurality of touch routing lines disposed in the active area AA or link lines which are electrically connected to a plurality of touch routing lines disposed in the active area AA, and pads which are electrically connected to the link lines may be disposed. The pads disposed in the non-active area NA may be bonded or electrically connected with the touch driving circuit.

In the non-active area NA, a part of an outermost touch electrode, among a plurality of touch electrodes disposed in the active area AA, expands or one or more electrodes (touch electrodes) formed of the same material as the plurality of touch electrodes disposed in the active area AA may be further disposed.

For example, all the plurality of touch electrodes disposed in the display panel DISP may be disposed in the display area AA or some (for example, an outermost touch electrode) among the plurality of touch electrodes disposed in the display panel DISP may be disposed in the non-display area NA. Some (for example, an outermost touch electrode) among the plurality of touch electrodes disposed in the display panel DISP may be disposed in both the display area AA and the non-display area NA.

In the meantime, referring to FIG. 2, the display panel DISP according to the first exemplary embodiment of the present disclosure may include a dam area DA having a dam for suppressing any layer (for example, the encapsulation unit in the display panel) in the active area AA from passing over the display panel DISP.

The dam area DA may be located at a boundary of the active area AA and the non-active area NA or at any one position of a non-active area NA which is an outer area of the active area AA.

The dam disposed in the dam area DA may be disposed to enclose all directions of the active area AA or disposed only at an outside of one or two or more parts of the active area AA.

The dam disposed in the dam area DA may have one pattern in which all the dams are connected or two or more separated patterns. Further, in the dam area DA, only a primary dam may be disposed or two or more dams (primary dam and secondary dam) may be disposed, or three or more dams may also be disposed.

For example, in the dam area DA, in any one direction, only the primary dam is disposed and in the other direction, both the primary dam and the secondary dam may be disposed.

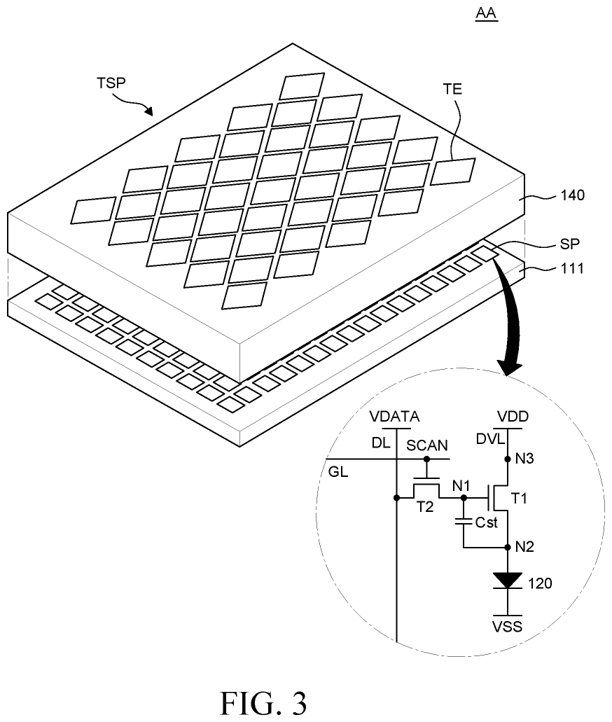

FIG. 3 is a perspective view illustrating a structure in which a touch panel is embedded in a display panel.

FIG. 3 is a perspective view illustrating a structure in which a touch panel is embedded in a display panel according to the first exemplary embodiment of the present disclosure.

Referring to FIG. 3, for example, in the active area AA of the display panel, a plurality of subpixels SP may be disposed above the substrate 111.

Each subpixel SP may include a light emitting diode 120, a first transistor T1 for driving the light emitting diode 120, a second transistor T2 for transmitting a data voltage VDATA to a first node N1 of the first transistor T1, and a storage capacitor Cst for maintaining a constant voltage for one frame.

For example, the first transistor T1 may include a first node N1 to which the data voltage VDATA is applied, a second node N2 which is electrically connected to the light emitting diode 120, and a third node N3 to which a driving voltage VDD is applied from a driving voltage line DVL. The first node N1 may be a gate node, the second node N2 is a source node or a drain node, and the third node N3 may be a drain node or a source node. The first transistor T1 may also be referred to as a driving transistor which drives the light emitting diode 120.

The light emitting diode 120 may include a first electrode (for example, an anode), an emission layer, and a second electrode (for example, a cathode). The first electrode is electrically connected to the second node N2 of the first transistor T1 and the second electrode may be applied with a base voltage VSS.

The emission layer in the light emitting diode 120 may be an emission layer including an organic material or an inorganic material.

For example, the second transistor T2 is controlled to be turned on or off by a scan signal SCAN applied through the gate line GL and may be electrically connected between the first node N1 of the first transistor T1 and the data line DL. Further, the second transistor T2 may be referred to as a switching transistor.

For example, when the second transistor T2 is turned on by the scan signal SCAN, the second transistor T2 transmits the data voltage VDATA supplied from the data line DL to the first node N1 of the first transistor T1.

Further, the storage capacitor Cst may be electrically connected between the first node N1 and the second node N2 of the first transistor T1.

As illustrated in FIG. 3, each subpixel SP may have a 2TIC structure including two transistors T1 and T2 and one capacitor Cst and in some cases, may further include one or more transistors or further include one or more capacitors.

The storage capacitor Cst is not a parasitic capacitor Cgs or Cgd which is an internal capacitor present between the first node N1 and the second node N2 of the first transistor T1, but may be an external capacitor which is intentionally designed at the outside of the first transistor T1.

The first transistor T1 and the second transistor T2 may be configured by an n-type transistor or a p-type transistor. As described above, in the display panel, circuit elements, such as a light emitting diode 120, two or more transistors T1 and T2, and one or more capacitors Cst are disposed. The circuit element (specifically, the light emitting diode 120) is vulnerable to external moisture or oxygen so that the encapsulation unit 140 for suppressing the external moisture or oxygen from permeating the circuit element may be disposed on the display panel.

The encapsulation unit 140 may be formed by one layer, or also formed by a plurality of layers.

In the meantime, in the display device according to the first exemplary embodiment of the present disclosure, the touch panel TSP may be disposed above the encapsulation unit 140. For example, in the display device according to the first exemplary embodiment of the present disclosure, a touch sensor structure, such as a plurality of touch electrodes TE which configures a touch panel TSP, may be disposed above the encapsulation unit 140.

During the touch sensing, a touch driving signal or a touch sensing signal may be applied to the touch electrode TE. Accordingly, during the touch sensing, a potential difference is formed between the touch electrode TE and the cathode which are disposed with the encapsulation unit 140 therebetween so that an unnecessary parasitic capacitance may be formed. At this time, the parasitic capacitance may degrade a touch sensitivity. Therefore, in order to lower the parasitic capacitance, a distance between the touch electrode TE and the cathode may be designed to be larger than a predetermined value (for example, 1 μm or larger) in consideration of a display panel thickness, a display panel manufacturing process, and a display performance. To this end, for example, the thickness of the encapsulation unit 140 may be designed to be at least 1 μm or larger.

In the meantime, the display device according to the first exemplary embodiment of the present disclosure may sense the touch based on capacitance formed in the touch electrode TE.

The display device according to the first exemplary embodiments of the present disclosure employs a capacitance based touch sensing manner so that the touch may be sensed by a mutual-capacitance based touch sensing manner or a self-capacitance based touch sensing manner.

For example, according to the mutual-capacitance based touch sensing manner, a plurality of touch electrodes TE may be classified into a driving touch electrode (a transmission touch electrode) to which a touch driving signal is applied and a sensing touch electrode (a reception touch electrode) which detects a touch sensing signal and forms a capacitance with the driving touch electrode.

In the case of the mutual-capacitance based touch sensing manner, the touch sensing circuit may sense the presence of the touch and/or the touch coordinate based on the change in capacitance (mutual-capacitance) between the driving touch electrode and the sensing touch electrode depending on the presence of a pointer such as a finger or a pen.

According to the self-capacitance based touch sensing manner, each touch electrode TE may serve as both a driving touch electrode and a sensing touch electrode. For example, the touch sensing circuit applies a touch driving signal to one or more touch electrodes TE and detects a touch sensing signal by means of the touch electrode TE applied with the touch driving signal. The touch sensing circuit identifies the change in capacitance between a pointer such as a finger or a pen and the touch electrode TE based on the detected touch sensing signal to sense the presence of touch and/or the touch coordinate. In the self-capacitance-based touch sensing manner, the driving touch electrode and the sensing touch electrode are not distinguished.

As described above, the display device according to the first exemplary embodiment of the present disclosure may sense the touch by the mutual-capacitance based touch sensing manner or the self-capacitance based touch sensing manner. However, in the following description, for the convenience of description, it will be described that the display device performs mutual-capacitance based touch sensing and includes a touch sensor structure therefor, as an example.

Hereinafter, a configuration of a subpixel will be described in detail with reference to the drawing.

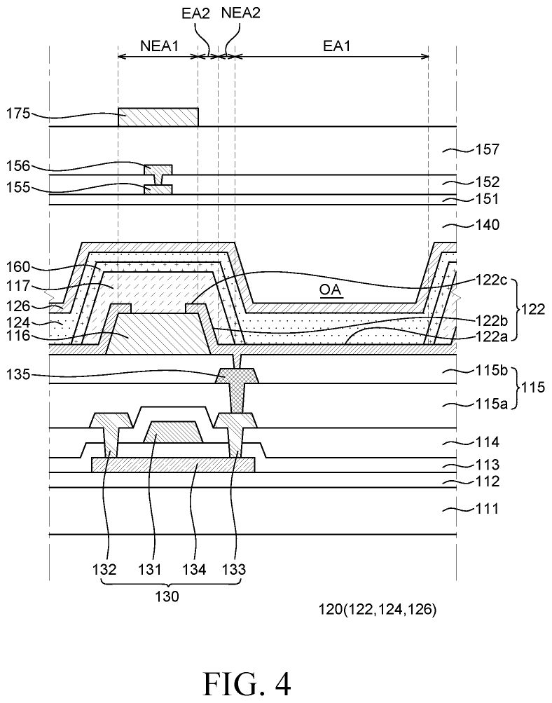

FIG. 4 is a cross-sectional view taken along the line I-I′ of FIG. 2, according to an embodiment of the present disclosure.

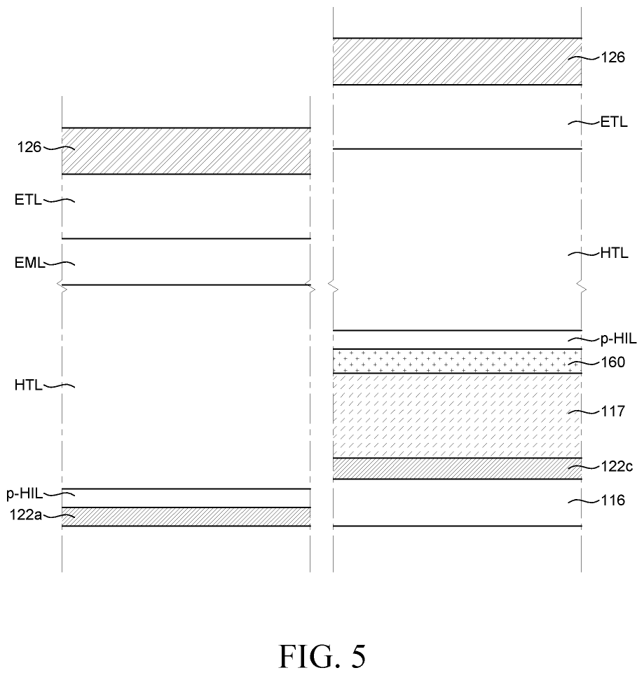

FIG. 5 is a view illustrating a lamination structure of a light emitting diode of FIG. 4, according to an embodiment of the present disclosure.

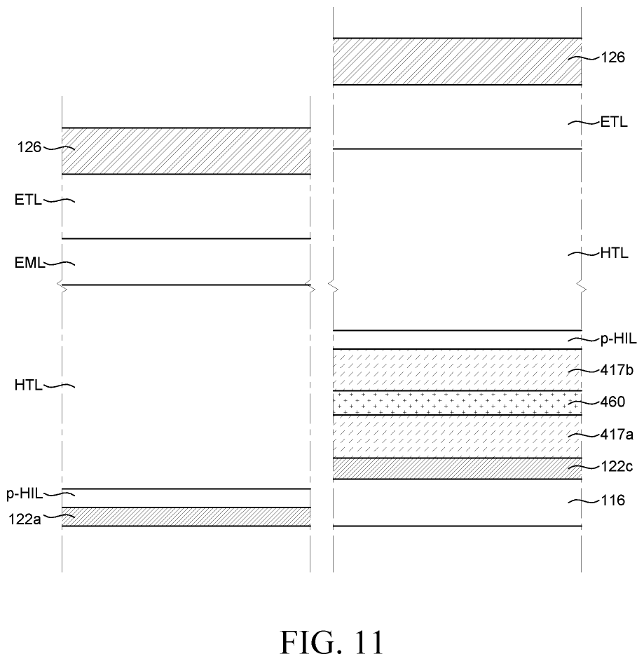

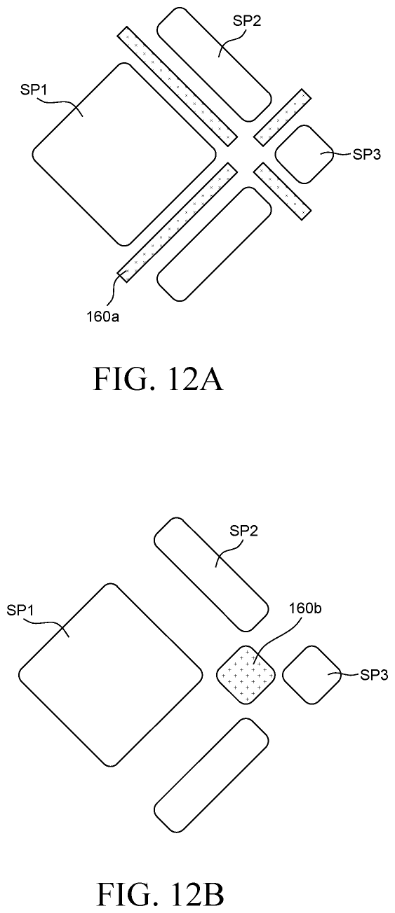

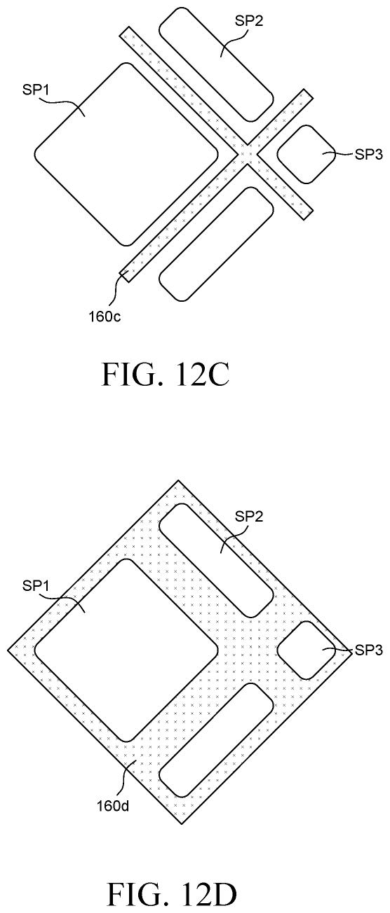

For example, FIG. 4 illustrates a part of a cross-sectional structure of one subpixel in a display panel according to the first exemplary embodiment of the present disclosure. The subpixel, a first subpixel, includes an anode electrode which includes a reflective material, at least a portion of an organic layer, and at least a part of a cathode electrode on the organic layer. Another subpixel, a second subpixel, may be spaced apart from and positioned adjacent to the first subpixel. For example, referring to FIG. 4, the second subpixel may be positioned in the area to the right of a first emission area EA1, or in the area to the left of a first non-emission area NEA1. This is illustrated and described in FIG. 12A to 12D.

Referring to FIG. 4, a buffer layer 112, such as a multi-buffer layer or a lower buffer layer, may be disposed above the substrate 111.

Recently, the flexible substrate 111 may use a ductile material having a flexible characteristic such as plastic.

The substrate 111 may be a film type including one of a group comprising of a polyester-based polymer, a silicon-based polymer, an acrylic-based polymer, a polyolefin-based polymer, and a copolymer thereof.

The substrate 111 may include a first substrate, a second substrate, and an insulating film. The insulating film may be disposed between the first substrate and the second substrate. As described above, the substrate 111 is configured by the first substrate, the second substrate, and the insulating film to suppress the moisture permeation. For example, the first substrate and the second substrate may be polyimide (PI) substrates.

For example, the multi-buffer layer may delay the spreading of the moisture or oxygen permeating the substrate 111 and may be formed by alternately laminating silicon nitride (SiNx) and silicon oxide (SiOx) at least one time.

For example, the lower buffer layer may perform a function of protecting the semiconductor layer 134 and blocking various types of defects entering from the substrate 111.

For example, the lower buffer layer may be formed by amorphous silicon, silicon nitride (SiNx), silicon oxide (SiOx), or the like.

The switching thin film transistor (T2 in the pixel driving circuit of FIG. 3) and the driving thin film transistor 130 (T1 in the pixel driving circuit of FIG. 3) may be disposed above the buffer layer 112.

Specifically, the semiconductor layer 134 may be disposed in the active area above the substrate 111.

For example, the semiconductor layer 134 is formed of a polycrystalline semiconductor and may include a channel region, a source region, and a drain region. However, it is not limited thereto and the semiconductor layer 134 may be configured by amorphous silicon or oxide semiconductor.

The polycrystalline semiconductor has a higher mobility than the amorphous semiconductor and the oxide semiconductor so that the power consumption is low and the reliability is excellent.

The gate insulating film 113 may be disposed on the semiconductor layer 134.

The gate insulating film 113 may be configured by a single layer of silicon nitride (SiNx) or silicon oxide (SiOx) or a multilayer thereof.

A gate line is disposed on the gate insulating film 113 in a first direction and a gate electrode 131 which is connected to the gate line or formed in an island shape may be disposed.

The gate electrode 131 may be disposed on the gate insulating film 113 so as to overlap the semiconductor layer 134.

For example, the gate electrode 131 and the gate line may be configured by a single layer or multilayers of copper (Cu), aluminum (Al), molybdenum (Mo), chrome (Cr), gold (Au), titanium (Ti), nickel (Ni), and neodymium (Nd) which are conductive metals or an alloy thereof, but is not limited thereto.

An interlayer insulating film 114 may be disposed on the gate electrode 131 so as to cover the gate electrode 131.

For example, the interlayer insulating film 114 may be configured by a single layer of silicon nitride (SiNx) or silicon oxide (SiOx) or a multilayer thereof.

At this time, a partial area of the interlayer insulating film 114 and the gate insulating film 113 is selectively removed to form a contact hole which exposes both ends of the semiconductor layer 134.

The data line may be disposed on the interlayer insulating film 114 in a direction intersecting the gate line.

Further, a source electrode 132 and a drain electrode 133 which are connected to both ends of the semiconductor layer 134 may be disposed on the interlayer insulating film 114.

A protective film may be disposed on the data line and the source electrode 132 and the drain electrode 133. The protective film may be omitted as needed.

The protective film may be formed as a single layer of silicon nitride (SiNx) or silicon oxide (SiOx) or a multilayer thereof.

A planarization film 115 may be disposed on the protective film.

The planarization film 115 may have a multi-layered structure configured by at least two layers and for example, may include a first planarization film 115a and a second planarization film 115b. The first planarization film 115a may be disposed to cover the driving thin film transistor 130 and expose a part of the source electrode 132 and the drain electrode 133 of the driving thin film transistor 130.

A thickness of the planarization film 115 is approximately 2 μm, but is not limited thereto.

The planarization film 115 may be an overcoat layer, but is not limited thereto.

For example, the connection electrode 135 may be disposed on the first planarization film 115a to electrically connect the driving thin film transistor 130 and the light emitting diode 120. Further, even though it is not illustrated in FIG. 4, various metal layers which serve as electric wires/electrodes, such as a data line or a signal line, may be disposed on the first planarization film 115a.

The connection electrode 135 may be configured with a material, such as copper (Cu), aluminum (Al), molybdenum (Mo), chrome (Cr), gold (Au), titanium (Ti), nickel (Ni), and neodymium (Nd), or an alloy thereof.

Further, the second planarization film 115b may be disposed on the first planarization film 115a and the connection electrode 135.

For example, since various signal lines are included in accordance with the increased resolution of the display panel, the planarization film 115 is formed by two layers in the display panel according to the first exemplary embodiment of the present disclosure. Therefore, it is difficult to dispose all the wiring lines on one layer while ensuring a minimum interval so that an additional layer is provided. Such an additional layer, for example, the second planarization film 115b is added so that there is a margin for disposing wiring lines, which makes it easier to design and dispose the wiring lines/electrodes. Further, when a dielectric material is used for the planarization film 115 configured by a plurality of layers, the planarization film 115 may be utilized to form a capacitance between metal layers.

The second planarization film 115b may be formed to expose a part of the connection electrode 135 and the drain electrode 133 of the driving thin film transistor 130 and the anode 122 of the organic light emitting diode 120 may be electrically connected by the connection electrode 135.

The planarization film 115 may be configured with one or more materials of acrylic resin, epoxy resin, phenolic resin, polyamides resin, polyimides resin, unsaturated polyesters resin, polyphenylene resin, benzocyclobutene, and polyphenylenesulfides resin, but is not limited thereto.

The first bank 116 may be disposed on the second planarization film 115b.

For example, the first bank 116 may be disposed in a first non-emission area NEA1 of the substrate 111 on the second planarization film 115b. In an embodiment, the first bank 116 may be disposed between a first subpixel and a second subpixel.

At this time, when the first bank 116 has a trapezoidal shape in which a lower side is wider than an upper side in a cross-sectional view, the first non-emission area NEA1 of the substrate 111 may be an area corresponding to the upper side of the first bank 116. In the plan view, the first bank 116 may include a top surface including the upper side, a bottom surface having a lower side, and a side surface connected from the top surface to the bottom surface.

The first bank 116 may be formed of an organic material. For example, the first bank 116 may be formed of polyimide, acrylic, or benzocyclobutene-based resin, but is not limited thereto.

Further, the first bank 116 may be formed of a black material. For example, the first bank 116 is configured such that the black pigment is dispersed in an organic material, but is not limited thereto and as long as the first bank has a black color, the first bank may be configured by an arbitrary black material. Further, for example, the organic material may be cardo-based polymer and polymer including epoxy acrylate, but is not limited thereto. As the first bank 116 includes the black material, the first bank 116 may reduce external light reflection, specifically, scattered reflection which may be generated by a transparent second bank 117. For example, in order to reduce the reflection of external light, an optical density of the first bank 116 may be 4 or lower at the thickness of 3 μm of the first bank 116, but is not limited thereto. Further, in order to reduce the reflection of the external light, the reflectance of the first bank 116 may be 1% or lower, but is not limited thereto.

Further, the light emitting diode 120 which is electrically connected to the connection electrode 135 through a contact hole may be disposed above the second planarization film 115b in which the first bank 116 is not disposed.

At this time, for example, the light emitting diode 120 may include an anode 122 connected to the drain electrode 133 of the driving thin film transistor 130, a plurality of organic layers 124 disposed on the anode 122, and a cathode 126 disposed on the organic layers 124. The organic layer 124 may be referred to as a light emitting unit, but is not limited to the term.

Further, for example, the anode 122 may include a first area 122a which is disposed on the second planarization film 115b to be in contact with the second planarization film 115b and a second area 112b which extends from the first area 122a to be disposed on the side surface of the first bank 116. The first area 112a has a surface substantially parallel to a surface of the substrate 111 and the second area 112b has a portion which has a predetermined angle with respect to the substrate 111.

Accordingly, the surface of the second area 122b may not be parallel to the surface of the substrate 111.

Further, the anode 122 may include a third area 122c which extends from the second area 122b to be in contact with the top surface of the first bank 116 and has a surface substantially parallel to a surface of the substrate 111. The third area 122c may be an area overlapping the top surface of the first bank 116.

For example, the third area 122c of the anode 122 may be spaced apart from the adjacent third area 122c with a predetermined distance to suppress the short-circuit between adjacent subpixels.

The anode 122 may be electrically connected to the source electrode 132 or the drain electrode 133 of the driving thin film transistor 130.

The anode 122 may include a reflective layer which is formed of a reflective metal.

Even though in FIG. 4, for the convenience of description, an example that the anode 122 is configured as a single layer, the present disclosure is not limited thereto and the anode may be configured with a multi-layered structure. When the anode 122 is configured with the multi-layered structure, at least one layer may include a reflective metal.

For example, the anode 122 may have a multi-layered structure including a transparent layer configured by a transparent conductive film and a reflective layer configured by an opaque conductive film having a high reflection efficiency. For example, the transparent conductive film is configured with a material having a relatively high work function, such as indium-tin-oxide (ITO) or indium-zinc-oxide (IZO) and the opaque conductive film may be configured with a single or multi-layered structure including copper (Cu), silver (Ag), aluminum (Al), molybdenum (Mo), titanium (Ti), or an alloy thereof. For example, the anode 122 is configured by a structure in which a transparent conductive film, an opaque conductive film, and a transparent conductive film are sequentially laminated or may be configured by a structure in which a transparent conductive film and an opaque conductive film are sequentially laminated.

In the meantime, the second area 122b of the anode 122 of the present disclosure may be disposed on the side surface of the first bank 116 along a shape of the side surface of the first bank 116. The second area 122b of the anode 122 disposed on the side surface of the first bank 116 may be tapered with an angle of approximately 30° to 60°, but is not limited thereto. Here, the second area 122b of the anode 122 including the reflective layer may serve as a side mirror (SM). Accordingly, the emission area according to the exemplary embodiments of the present disclosure may further include an auxiliary emission area EA2 by the SM structure, as well as the main emission area EA1. The auxiliary emission area EA2 may be formed between the main emission area EA1 corresponding to the second area 122b of the anode 122 and the first non-emission area NEA1.

When the display device according to the exemplary embodiments of the present disclosure is a top emission type light emitting display device, the reflective layer of the anode 122 may upwardly reflect the light emitted from the light emitting diode 120. The light generated in the organic layer 124 of the light emitting diode 120 may be emitted not only upwardly, but also laterally. The laterally emitted light is directed into the display device, or trapped in the display device by the total reflection, or travels into the display device and then dissipates. Therefore, according to the present disclosure, the second area 122b of the anode 122 including the reflective layer may be disposed on the side surface of the first bank 116 to change a traveling direction of light which laterally travels to an upward direction. Therefore, the light extraction efficiency of the display device may be improved.

For example, the second bank 117 may be disposed above the first bank 116 and the anode 122 while covering a part of the anode 122.

For example, the second bank 117 may cover a part of the first area 122a and the second area 122b and the third area 122c of the anode 122. The second bank 117 may cover a part of an edge of the first area 122a.

A part of the second bank 117 corresponding to the main emission area EA1 may be open.

For example, the second bank 117 may include an open area OA obtained by removing (opening) a part corresponding to the main emission area EA1 of a subpixel.

The second bank 117 may include a top surface, a side portion, and a bottom surface.

A top surface of the second bank 117 is a surface located at the top of the second bank 117 and is substantially parallel to the substrate 111. Further, the top surface of the second bank 117 may correspond to the top surface of the first bank 116.

A side portion of the second bank 117 is a surface extending from the top surface of the second bank 117 to a side surface. A side portion of the second bank 117 may have a predetermined taper angle. For example, a side portion of the second bank 117 may have a taper angle of 30° to 65°, but is not limited thereto. The side portion of the second bank 117 may correspond to the side surface of the first bank 116.

Next, a bottom surface unit of the second bank 117 may correspond to a surface which abuts with the anode 122 in the first area 122a of the anode 122.

Further, the bottom surface of the second bank 117 may correspond to a second non-emission area NEA2 between the main emission area EA1 and the reflective emission area EA2.

Therefore, the subpixel according to the present disclosure may have a plurality of emission areas EA1 and EA2 and a plurality of non-emission areas NEA1 and NEA2. In each subpixel, the main emission area EA1 may have a larger width than the reflective emission area EA2. In each subpixel, the first non-emission area NEA1 may have a larger width than the second non-emission area NEA2, but it is not limited thereto.

The second bank 117 may be formed of an organic material. For example, the second bank 117 may be formed of polyimide, acrylic, or benzocyclobutene-based resin, but is not limited thereto.

Further, the second bank 117 may be formed of a transparent material, but is not limited thereto.

In the meantime, a doping layer 160 may be disposed on a top surface and a side portion of the second bank 117.

For example, the doping layer 160 may be disposed on the top surface and the side portion of the second bank 117 so as to cover the second bank 117.

For example, the doping layer 160 may be a p-doping layer 160 which is formed by injecting a dopant, such as a p-type impurity to have a cationic property.

For example, the p-type impurity may include boron (B), indium (In), gallium (Ga), or the like.

The p-doping layer 160 may suppress the device defect caused by the anions generated in the first bank 116 which is configured by a black material.

For example, anions (S²⁻, Cl⁻, Br⁻), such as sulfur (S), chlorine (Cl), and bromine (Br), are generated in the first bank 116 which is formed of a black material to affect the anode 122 or a hole injection layer or an electron injection layer of the organic layer 124, which may cause defects.

Accordingly, according to the first exemplary embodiment of the present disclosure, the p-doping layer 160 may be disposed on the top surface and the side portion of the second bank 117 so as to cover the first bank 116 and the second bank 117 to suppress the device defect by the anions. That is, the anions S²⁻, Cl⁻, Br⁻ which are impurities generated in the first bank 116 react with cations generated in the p-doping layer 160 so that the reaction with the anode 122 and the organic layer 124 may be blocked.

For example, it is understood that as a result of increasing a concentration of a p-doping layer 160 with a positive (+) charge, the degradation of hole injection characteristic by the anions with a negative (−) charge may be suppressed.

Further, it is also understood that the p-doping layer 160 minimizes the leakage current, and for example, it is understood that as a result of increasing the doping concentration from 0.6% to 1.8%, the leakage current is reduced by approximately 30 to 70%.

The organic layer 124 may be disposed on the top surface and a side portion of the second bank 117 and the doping layer 160, including the open area OA of the second bank 117.

For example, the organic layer 124 may include a hole injection layer, a hole transport layer, an emission layer, an electron transport layer, and an electron injection layer. In a tandem structure in which a plurality of emission layers is overlaid, a charge generation layer may be further disposed between the emission layers. The emission layer may emit different color light in every subpixel. For example, a red emission layer, a green emission layer, and a blue emission layer may be separately disposed in every subpixel, but is not limited thereto. However, a common emission layer is formed in every subpixel to emit white light regardless of the color and a color filter which distinguishes the color may be separately provided. In this case, the emission layer may be individually disposed, but the hole injection layer, the electron injection layer, the hole transport layer, or the electron transport layer is provided as a common layer to be disposed in each subpixel in the same way.

Further, the cathode 126 may be disposed on the organic layer 124 so as to be opposite to the anode 122 with the organic layer 124 therebetween. For example, when the cathode 126 is applied to a top emission type display device, the cathode may be configured by a transparent conductive film obtained by forming indium tin oxide (ITO), indium zinc oxide (IZO), or magnesium-silver (Mg-AG) to be thin.

Hereinafter, a lamination structure of the light emitting diode 120 according to the first exemplary embodiment of the present disclosure will be described in more detail with reference to FIG. 5 together.

A left side of FIG. 5 illustrates a lamination structure of the light emitting diode 120 in the main emission area EA1 and a right side of FIG. 5 illustrates a lamination structure of the light emitting diode 120 in the first non-emission area NEA1 including the third area 122c of the anode 122.

Referring to FIGS. 4 and 5, the first bank 116 may be disposed in a first non-emission area NEA1 of the substrate 111 on the second planarization film 115b. The first bank 116 may be disposed between a first subpixel and a second subpixel.

The first bank 116 may be formed of an organic material. For example, the first bank 116 may be formed of polyimide, acrylic, or benzocyclobutene-based resin, but is not limited thereto.

Further, the first bank 116 may be formed of a black material.

The anode 122 may be disposed on the first bank 116.

At this time, for example, the anode 122 may include a first area 122a which may be disposed on the second planarization film 115b to be in contact with the second planarization film 115b and a second area 112b which extends from the first area 122a to be disposed on the side surface of the first bank 116. The first area 112a has a surface substantially parallel to a surface of the substrate 111 and the second area 112b has a surface which has a predetermined angle with respect to the substrate 111.

Further, the anode 122 may include a third area 122c which extends from the second area 122b to be in contact with the top surface of the first bank 116 and has a surface substantially parallel to a surface of the substrate 111. The third area 122c may be an area overlapping the top surface of the first bank 116.

The anode 122 may include a reflective layer which is formed of a reflective metal.

Further, the second area 122b of the anode 122 of the present disclosure may be disposed on the side surface of the first bank 116 along a shape of the side surface of the first bank 116. Here, the second area 122b of the anode 122 including the reflective layer may serve as a side mirror (SM).

For example, the second bank 117 may be disposed above the first bank 116 and the anode 122 while covering a part of the first area 122a and the second area 122b and the third area 122c of the anode 122.

For example, the second bank 117 may include an open area OA obtained by removing (opening) a part corresponding to the main emission area EA1 of a subpixel.

The second bank 117 may be formed of an organic material. For example, the second bank 117 may be formed of polyimide, acrylic, or benzocyclobutene-based resin, but is not limited thereto.

Further, the second bank 117 may be formed of a transparent material, but is not limited thereto.

For example, the doping layer 160 may be disposed on the top surface and the side portion of the second bank 117 so as to cover the second bank 117.

For example, the doping layer 160 may be a p-doping layer 160 which is formed by injecting a p-type impurity.

For example, the p-doping layer 160 may be formed using an evaporation process, but is not limited thereto.

The organic layer 124 may be disposed on the top surface and a side portion of the second bank 117 and the doping layer 160 including the open area OA of the second bank 117.

The organic layer 124 may include a p-hole injection layer p-HIL, a hole transport layer HTL, an emission layer EML, an electron transport layer ETL, and an electron injection layer.

The p-hole injection layer p-HIL may be disposed on the entire surface of the substrate 111 on which the p-doping layer 160 is disposed. In the p-hole injection layer p-HIL, a p-type impurity may be included in the hole injection layer. Here, the entire area of the substrate 111 refers to an entire surface of the active area and may also include a part of the non-active area.

According to the first exemplary embodiment of the present disclosure, the p-doping layer 160 may have a higher doping concentration than the p-hole injection layer p-HIL and the p-hole injection layer p-HIL may have the same thickness on the entire surface of the substrate 111, but is not limited thereto.

For example, the p-doping layer 160 may have a thickness of 100 Å with a doping concentration of approximately 1.6% and the p-hole injection layer p-HIL may have a thickness of 100 Å with a doping concentration of approximately 0.62%, but is not limited thereto.

Further, the hole transport layer HTL may be disposed on the entire surface of the substrate 111 on which the p-hole injection layer p-HIL is disposed.

For example, the p-hole injection layer p-HIL and the hole transport layer HTL may be common layers which are commonly disposed in all the subpixels.

Further, the emission layer EML may be disposed on the hole transport layer HTL of the main emission area EA1.

For example, the emission layer EML may be an individual layer which is individually disposed for every subpixel.

The emission layer EML may emit different color light in every subpixel. For example, a red emission layer EML, a green emission layer EML, and a blue emission layer EML may be separately disposed in every subpixel, but are not limited thereto. For example, a common emission layer is formed in every subpixel to emit white light regardless of the color and a color filter which distinguishes the color may be separately provided. In this case, the emission layer may be individually disposed.

Further, the electron transport layer ETL may be disposed on the entire surface of the substrate 111 on which the emission layer EML is disposed.

For example, the electron transport layer ETL may be a common layer.

Even though it is not illustrated, the electron injection layer may be further disposed on the electron transport layer ETL.

Further, the cathode 126 may be disposed on the entire surface of the substrate 111 on which the electron transport layer ETL is disposed.

Referring to FIG. 4 again, an encapsulation unit 140 may be disposed above the cathode 126 to protect the light emitting diode 120.

For example, the light emitting diode 120 may react to external moisture and oxygen due to a characteristic of the organic material of the organic layer 124 to cause dark-spot or pixel shrinkage. In order to suppress this problem, the encapsulation unit 140 may be disposed above the cathode 126. Even though it is not illustrated, the encapsulation unit 140 may be configured by a first inorganic insulating film, a foreign material compensation layer, and a second inorganic insulating film.

The first inorganic insulating film may be disposed above the substrate 111 in which the cathode 126 is disposed to be the most adjacent to the light emitting diode 120.

For example, the first inorganic encapsulation film may be configured by an inorganic insulating material on which low-temperature deposition is allowed, such as silicon nitride (SiNx), silicon oxide (SiOx), silicon oxynitride (SiON), or aluminum oxide (Al₂O₃). The first inorganic insulating film is deposited under a low temperature atmosphere so that the damage of the organic layer 124 including an organic material vulnerable to the high temperature atmosphere during the deposition may be suppressed.

A foreign material compensation layer may be disposed to have a smaller area than the first inorganic insulating film and may be configured to expose both ends of the first inorganic insulating film. The foreign material compensation layer may be formed of an organic insulating material, such as acrylic resin, epoxy resin, polyimide, polyethylene, or silicon oxy carbon (SiOC).

In the meantime, when the foreign material compensation layer is formed by an inkjet method, one or more dams may be disposed in a boundary area of the non-active area and the active area or a dam area corresponding to a partial area in the non-active area may be disposed. In such a dam area, a primary dam adjacent to the active area and a secondary dam adjacent to the pad unit may be disposed.

When a liquid type foreign material compensation layer is dropped in the active area, one or more dams disposed in the dam area may suppress the liquid type foreign material compensation layer from collapsing in the direction of the non-active area to invade the pad unit.

The primary dam and/or secondary dam may be configured as a single layer or a multi-layered structure. For example, the primary dam and/or secondary dam may be simultaneously configured with the same material as at least one of the planarization film 115, the first bank 116, the second bank 117, and the spacer. In this case, the dam structure may be configured without having the mask adding process and increasing the cost.

Further, the foreign material compensation layer including an organic material may be located only on an inner surface of the primary dam.

Further, the second inorganic insulating film may be disposed so as to cover an upper surface and a side surface of each of the first inorganic insulating film and the foreign material compensation layer. The second inorganic insulating film may serve to minimize or block the permeation of the external moisture or oxygen into the first inorganic insulating film and the foreign material compensation layer. The second inorganic insulating film may be formed of an inorganic insulating material, such as silicon nitride (SiNx), silicon oxide (SiOx), silicon oxynitride (SiON), or aluminum oxide (Al₂O₃).

A touch buffer film 151 may be disposed on the encapsulation unit 140.

A bridge pattern 155 may be disposed on the touch buffer film 151. However, it is not limited thereto and a touch electrode (or, a touch line) may be disposed on the touch buffer film 151.

The touch buffer film 151 may be located between the bridge pattern 155 and the encapsulation unit 140.

For example, the touch buffer film 151 may be designed to maintain a predetermined minimum interval between the bridge pattern 155 and the cathode 126. By doing this, a parasitic capacitance which may be formed between the bridge pattern 155 and the cathode 126 may be reduced or suppressed so that a touch sensitivity degradation due to the parasitic capacitance may also be suppressed.

The bridge pattern 155 may be disposed above the encapsulation unit 140 without having the touch buffer film 151.

The bridge pattern 155 may have a single-layer or multi-layered structure formed of a metal having strong corrosion resistance and acid resistance, such as aluminum (Al), titanium (Ti), copper (Cu), or molybdenum (Mo).

The touch insulting film 152 may be disposed on the bridge pattern 155.

For example, the touch insulating film 152 may use an organic film or an inorganic film which can be formed by a low temperature process. When the organic film is used for the touch insulating film 152, after coating the organic film above the substrate 111, the organic film is cured at a temperature of 100° C. or lower to form the touch insulating film 152 to suppress the damage of the organic layer 124 vulnerable to the high temperature. When the inorganic film is used for the touch insulating film 152, in order to suppress the damage of the organic layer 124 vulnerable to the high temperature, a low temperature chemical vapor deposition (CVD) process and a washing process are repeated at least two times to form the touch insulating film 152 with a multi-layered structure.

A partial area of the touch insulating film 152 is selectively removed to form a touch contact hole to expose a part of the bridge pattern 155.

A touch electrode (or, a touch line) 156 may be disposed on the touch insulating film 152. However, it is not limited thereto and the bridge pattern may be disposed on the touch insulating film 152.

For example, the touch electrode 156 may be electrically connected to the bridge pattern 155 through the touch contact hole.

The planarization film 157 may be disposed on the touch electrode 156, but is not limited thereto and the planarization film may be omitted.

A black matrix 175 may be disposed on the planarization film 157.

The black matrix 175 may be located above the touch electrode 156.

The black matrix 175 may be located so as to correspond to the top surface of the first bank 116. That is, a width of the black matrix 175 may be reduced by the black first bank 116. For example, the black matrix 175 may have a width corresponding to the top surface of the first bank 116.

In the meantime, the p-doping layer of the present disclosure may be disposed on the entire surface of the substrate, which will be described in detail with reference to the drawing.

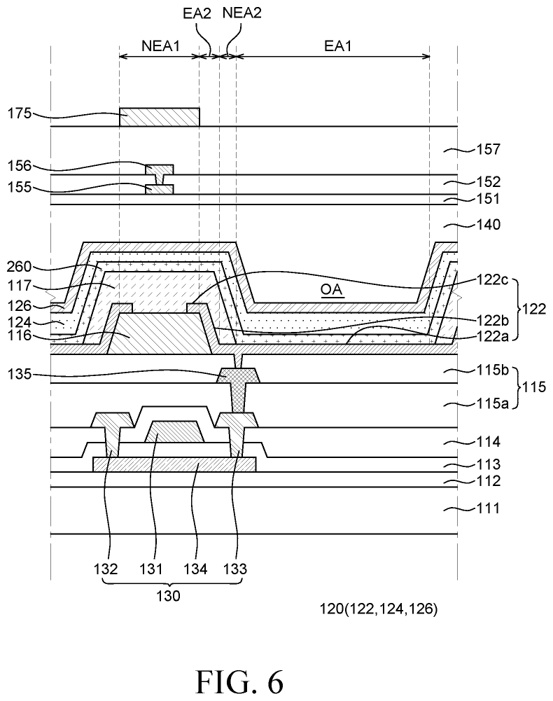

FIG. 6 is a view illustrating a part of a cross-section of a display panel according to a second exemplary embodiment of the present disclosure.

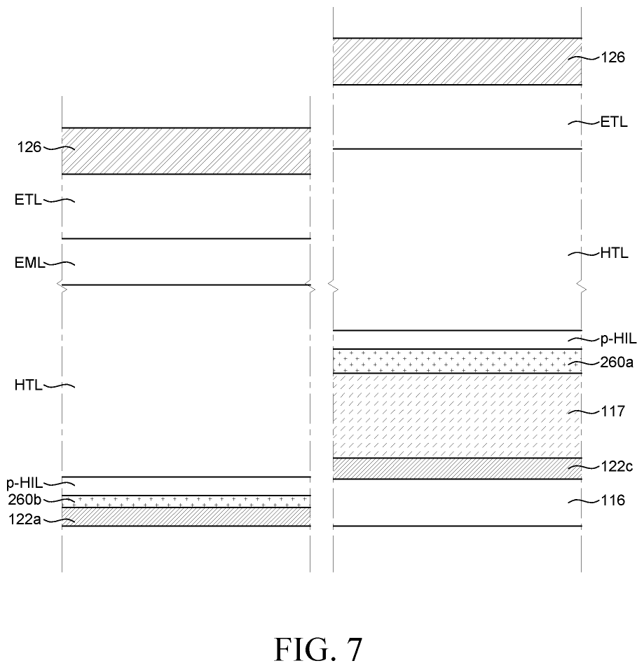

FIG. 7 is a view illustrating a lamination structure of a light emitting diode of FIG. 6, according to an embodiment of the present disclosure.

A second exemplary embodiment of the present disclosure of FIGS. 6 and 7 has a different configuration of the p-doping layer 260 from that of the first exemplary embodiment of the present disclosure of FIGS. 4 and 5 described above, but other configurations are substantially the same so that a redundant description will be omitted.

For example, FIG. 6 illustrates a part of a cross-sectional structure of one subpixel of a display panel according to the second exemplary embodiment of the present disclosure.

Further, a left side of FIG. 7 illustrates a lamination structure of the light emitting diode 120 in the main emission area EA1 and a right side of FIG. 7 illustrates a lamination structure of the light emitting diode 120 in the first non-emission area NEA1 including the third area 122c of the anode 122.

Referring to FIGS. 6 and 7, a planarization film 115 may be disposed above the substrate 111.

The first bank 116 may be disposed above the planarization film 115.

For example, the first bank 116 may be disposed in a first non-emission area NEA1 of the substrate 111.

The first bank 116 may be formed of an organic material. For example, the first bank 116 may be formed of polyimide, acrylic, or benzocyclobutene-based resin, but is not limited thereto.

Further, the first bank 116 may be formed of a black material.

The anode 122 may be disposed on the first bank 116.

At this time, for example, the anode 122 may include a first area 122a which is disposed on the second planarization film 115b to be in contact with the second planarization film 115b and a second area 112b which extends from the first area 122a to be disposed on the side surface of the first bank 116. The first area 112a has a surface substantially parallel to a surface of the substrate 111 and the second area 112b has a surface which has a predetermined angle with respect to the substrate 111.

Further, the anode 122 may include a third area 122c which extends from the second area 122b to be in contact with the top surface of the first bank 116 and has a surface substantially parallel to a surface of the substrate 111. The third area 122c may be an area overlapping the top surface of the first bank 116.

The anode 122 may include a reflective layer which is formed of a reflective metal.

Further, the second area 122b of the anode 122 of the present disclosure may be disposed on the side surface of the first bank 116 along a shape of the side surface of the first bank 116.

For example, the second bank 117 may be disposed above the first bank 116 and the anode 122 while covering a part of the first area 122a and the second area 122b and the third area 122c of the anode 122.

For example, the second bank 117 may include an open area OA obtained by removing (opening) a part corresponding to the main emission area EA1 of a subpixel.

The second bank 117 may be formed of an organic material. For example, the second bank 117 may be formed of polyimide, acrylic, or benzocyclobutene-based resin, but is not limited thereto.

Further, the second bank 117 may be formed of a transparent material, but is not limited thereto.

A doping layer 260 may be disposed on the entire surface of the substrate 111 so as to cover the second bank 117.

For example, the doping layer 260 may be a p-doping layer 260 which is formed by injecting a p-type impurity.

The p-doping layer 260 according to the second exemplary embodiment of the present disclosure may have different thicknesses in the first non-emission area NEA1 and the main emission area EA1, but is not limited thereto.

For example, the p-doping layer 260 may be configured by a first p-doping layer 260a having a first thickness and a second p-doping layer 260b having a second thickness.

For example, the first p-doping layer 260a is disposed so as to correspond to the first non-emission area NEA1 and the second non-emission area NEA2 and the auxiliary emission area EA2, and the second p-doing layer 260b may be disposed so as to correspond to the main emission area EA1. However, it is not limited thereto and the second p-doping layer 260b may be disposed in the second non-emission area NEA2 and/or the auxiliary emission area EA2.

When the p-doping layer 260 may be disposed on the entire surface of the substrate 111, in consideration of the p-hole injection layer p-HIL of the main emission area EA1, the first p-doping layer 260a may apply a thickness smaller than the p-doping layer 160 of the first exemplary embodiment. Further, as compared with the main emission area EA1, in consideration of the first p-doping layer 260a, in the first non-emission area NEA1, the second p-doing layer 260b may apply a thickness larger than the p-doping layer 160 of the first exemplary embodiment.

The first thickness may be larger than the second thickness. Further, the first thickness is larger than the p-doping layer 160 of the first exemplary embodiment and the second thickness is smaller than the p-doping layer 160 of the first exemplary embodiment.

For example, the first thickness may be approximately 172 Å and the second thickness may be approximately 72 Å.

For example, the first p-doping layer 260a and the second p-doping layer 260b may have a doping concentration of approximately 1.6%, but are not limited thereto.

The p-hole injection layer p-HIL may be disposed on the entire surface of the substrate 111 on which the p-doping layer 260 is disposed.

According to the second exemplary embodiment of the present disclosure, the p-doping layer 260 may have a higher doping concentration than the p-hole injection layer p-HIL and the p-hole injection layer p-HIL may have the same thickness on the entire surface of the substrate 111, but is not limited thereto.

For example, the p-hole injection layer p-HIL may have a thickness of 72 Å with a doping concentration of approximately 0.62%, but is not limited thereto.

Further, the hole transport layer HTL may be disposed on the entire surface of the substrate 111 on which the p-hole injection layer p-HIL is disposed.

For example, the p-hole injection layer p-HIL and the hole transport layer HTL may be common layers which are commonly disposed in all the subpixels.

Further, the emission layer EML may be disposed on the hole transport layer HTL of the main emission area EA1.

For example, the emission layer EML may be an individual layer which is individually disposed for every subpixel.

Further, the electron transport layer ETL may be disposed on the entire surface of the substrate 111 on which the emission layer EML is disposed.

For example, the electron transport layer ETL may be a common layer.

Even though it is not illustrated, the electron injection layer may be further disposed on the electron transport layer ETL.

Further, the cathode 126 may be disposed on the entire surface of the substrate 111 on which the electron transport layer ETL is disposed.

An encapsulation unit 140 may be disposed above the cathode 126.

For example, the encapsulation unit 140 may be configured by a first inorganic insulating film, a foreign material compensation layer, and a second inorganic insulating film.

A touch panel including a touch buffer film 151, a bridge pattern 155, a touch insulating film 152, and a touch electrode (or, a touch line) 156 may be disposed above the encapsulation unit 140.

The planarization film 157 and the black matrix 175 may be disposed above the touch panel.

The black matrix 175 may be located so as to correspond to the top surface of the first bank 116.

For example, the black matrix 175 may have a width corresponding to the top surface of the first bank 116.

In the meantime, the p-doping layer of the present disclosure may be formed in the second bank using an ion implantation process, in addition to the evaporation process, which will be described in detail with reference to the drawing.

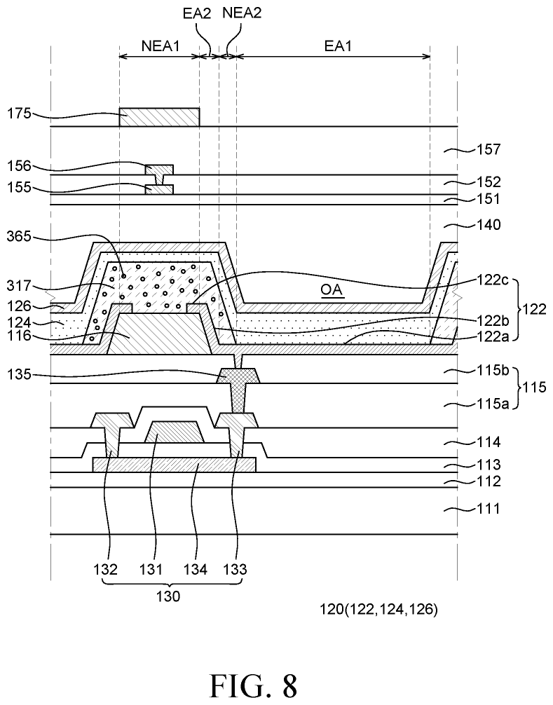

FIG. 8 is a view illustrating a part of a cross-section of a display panel according to a third exemplary embodiment of the present disclosure.

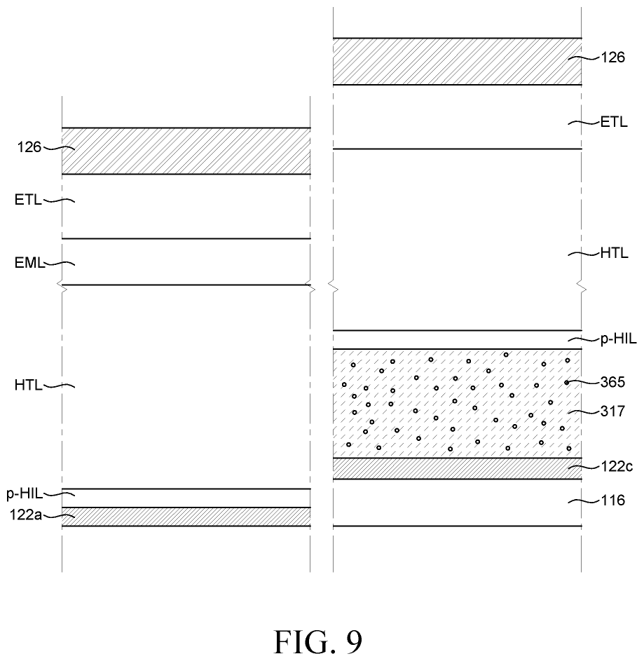

FIG. 9 is a view illustrating a lamination structure of a light emitting diode of FIG. 8.

A third exemplary embodiment of the present disclosure of FIGS. 8 and 9 has a different configuration of a second bank 317 from that of the first exemplary embodiment of the present disclosure of FIGS. 4 and 5 described above, but other configurations are substantially the same so that a redundant description will be omitted.

For example, FIG. 8 illustrates a part of a cross-sectional structure of one subpixel of a display panel according to the third exemplary embodiment of the present disclosure.

Further, a left side of FIG. 9 illustrates a lamination structure of the light emitting diode 120 in the main emission area EA1 and a right side of FIG. 9 illustrates a lamination structure of the light emitting diode 120 in the first non-emission area NEA1 including the third area 122c of the anode 122.

Referring to FIGS. 8 and 9, a planarization film 115 may be disposed above the substrate 111.

The first bank 116 may be disposed on the planarization film 115.

For example, the first bank 116 may be disposed in a first non-emission area NEA1 of the substrate 111.

The first bank 116 may be formed of an organic material. For example, the first bank 116 may be formed of polyimide, acrylic, or benzocyclobutene-based resin, but is not limited thereto.

Further, the first bank 116 may be formed of a black material.

The anode 122 may be disposed on the first bank 116.

As described above, the anode 122 may include a first area 122a, a second area 122b, and a third area 122c.

Further, the second area 122b of the anode 122 of the present disclosure may be disposed on the side surface of the first bank 116 along a shape of the side surface of the first bank 116.

For example, the second bank 317 may be disposed above the first bank 116 and the anode 122 while covering a part of the first area 122a and the second area 122b and the third area 122c of the anode 122.

For example, the second bank 317 may include an open area OA obtained by removing (opening) a part corresponding to the main emission area EA1 of a subpixel.

The second bank 317 may be formed of an organic material. For example, the second bank 317 may be formed of polyimide, acrylic, or benzocyclobutene-based resin, but is not limited thereto.

Further, the second bank 317 may be formed of a transparent material, but is not limited thereto.

Further, the second bank 317 of the third exemplary embodiment of the present disclosure may include dopants, such as a p-type impurity 365 having a positive charge.

For example, the p-type impurity 365 may include boron (B), indium (In), gallium (Ga), or the like.

In the second bank 317 of the third exemplary embodiment of the present disclosure, impurities 365 with a positive charge are dispersed between organic materials to react with an anion generated in the first bank 116 so that the second bank may have the same function and effect as the p-doping layer of the first and second exemplary embodiments.

The p-hole injection layer p-HIL may be disposed on the entire surface of the substrate 111 on which the second bank 317 is disposed.

Further, the hole transport layer HTL may be disposed on the entire surface of the substrate 111 on which the p-hole injection layer p-HIL is disposed.

Further, the emission layer EML may be disposed on the hole transport layer HTL of the main emission area EA1.

Further, the electron transport layer ETL may be disposed on the entire surface of the substrate 111 on which the emission layer EML is disposed.

Even though it is not illustrated, the electron injection layer may be further disposed on the electron transport layer ETL.

Further, the cathode 126 may be disposed on the entire surface of the substrate 111 on which the electron transport layer ETL is disposed.

An encapsulation unit 140 may be disposed above the cathode 126.

A touch panel including a touch buffer film 151, a bridge pattern 155, a touch insulating film 152, and a touch electrode (or, a touch line) 156 may be disposed above the encapsulation unit 140.

The planarization film 157 and the black matrix 175 may be disposed above the touch panel.

The black matrix 175 may be located so as to correspond to the top surface of the first bank 116.

For example, the black matrix 175 may have a width corresponding to the top surface of the first bank 116.

In the meantime, the p-doping layer of the present disclosure may be inserted into the multi-layered second bank, which will be described in detail with reference to the drawing.

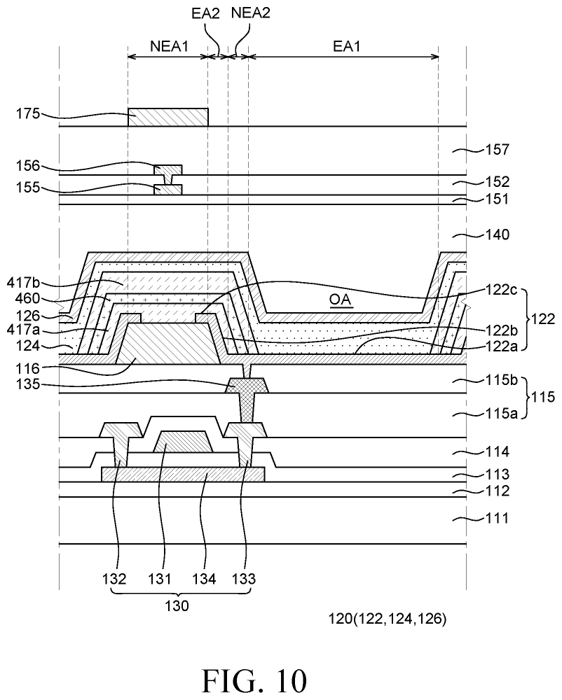

FIG. 10 is a view illustrating a part of a cross-section of a display panel according to a fourth exemplary embodiment of the present disclosure.

FIG. 11 is a view illustrating a lamination structure of a light emitting diode of FIG. 10.

A fourth exemplary embodiment of the present disclosure of FIGS. 10 and 11 has different configurations of second banks 417a and 417b and a p-doping layer 460 from those of the first exemplary embodiment of the present disclosure of FIGS. 4 and 5 described above, but other configurations are substantially the same. Therefore, a redundant description will be omitted.

For example, FIG. 10 illustrates a part of a cross-sectional structure of one subpixel of a display panel according to the fourth exemplary embodiment of the present disclosure.

Further, a left side of FIG. 11 illustrates a lamination structure of the light emitting diode 120 in the main emission area EA1, and a right side of FIG. 11 illustrates a lamination structure of the light emitting diode 120 in the first non-emission area NEA1 including the third area 122c of the anode 122.

Referring to FIGS. 10 and 11, a planarization film 115 may be disposed above the substrate 111.

The first bank 116 may be disposed on the planarization film 115.

For example, the first bank 116 may be disposed in a first non-emission area NEA1 of the substrate 111.

The first bank 116 may be formed of an organic material. For example, the first bank 116 may be formed of polyimide, acrylic, or benzocyclobutene-based resin, but is not limited thereto.

Further, the first bank 116 may be formed of a black material.

The anode 122 may be disposed on the first bank 116.

As described above, the anode 122 may include a first area 122a, a second area 122b, and a third area 122c.

Further, the second area 122b of the anode 122 of the present disclosure may be disposed on the side surface of the first bank 116 along a shape of the side surface of the first bank 116.

For example, the second banks 417a and 417b may be disposed above the first bank 116 and the anode 122 while covering a part of the first area 122a and the second area 122b and the third area 122c of the anode 122.

For example, the second banks 417a and 417b may include an open area OA obtained by removing (opening) a part corresponding to the main emission area EA1.

The second banks 417a and 417b may be formed of an organic material. For example, the second banks 417a and 417b may be formed of polyimide, acrylic, or benzocyclobutene-based resin, but is not limited thereto.

Further, the second banks 417a and 417b may be formed of a transparent material, but is not limited thereto.

The second bank 417a and 417b of the fourth exemplary embodiment of the present disclosure may be configured by a double layered structure of a first-second bank 417a and a second-second bank 417b, but the present disclosure is not limited thereto, and may be configured by a multi-layered structure of three or more layers.

According to the fourth exemplary embodiment of the present disclosure, a p-doping layer 460 may be disposed between the first-second bank 417a and the second-second bank 417b of the double-layered structure. For example, the p-doping layer 460 is disposed on the first-second bank 417a and the second-second bank 417b may be disposed on the p-doping layer 460.

For example, the p-doping layer 460 may be disposed on a top surface and a side portion of the first-second bank 417a so as to cover the first-second bank 417a.

Further, for example, the second-second bank 417b may be disposed on the top surface and the side portion of the p-doping layer 460 so as to cover the p-doping layer 460.

The p-hole injection layer p-HIL may be disposed on the entire surface of the substrate 111 on which the second banks 417a and 417b are disposed.

Further, the hole transport layer HTL may be disposed on the entire surface of the substrate 111 on which the p-hole injection layer p-HIL is disposed.

Further, the emission layer EML may be disposed on the hole transport layer HTL of the main emission area EA1.

Further, the electron transport layer ETL may be disposed on the entire surface of the substrate 111 on which the emission layer EML is disposed.

Even though it is not illustrated, the electron injection layer may be further disposed on the electron transport layer ETL.

Further, the cathode 126 may be disposed on the entire surface of the substrate 111 on which the electron transport layer ETL is disposed.

An encapsulation unit 140 may be disposed above the cathode 126.

A touch panel including a touch buffer film 151, a bridge pattern 155, a touch insulating film 152, and a touch electrode (or, a touch line) 156 may be disposed above the encapsulation unit 140.

The planarization film 157 and the black matrix 175 may be disposed above the touch panel.

The black matrix 175 may be located so as to correspond to the top surface of the first bank 116.

For example, the black matrix 175 may have a width corresponding to the top surface of the first bank 116.

In the meantime, the p-doping layer according to the above-described exemplary embodiments may be applied to various pixel structures, which will be described in detail with reference to the drawings.

FIGS. 12A to 12D are views illustrating a pixel structure according to exemplary embodiments of the present disclosure.

At this time, FIGS. 12A to 12D illustrate one pixel structure configured by one first subpixel SP1, two second subpixels SP2, and one third subpixel SP3 as an example, but the present disclosure is not limited thereto. In some embodiments, the pixel structure includes a fourth subpixel SP4.

Referring to FIGS. 12A to 12D, the display panel of the exemplary embodiments of the present disclosure may include a plurality of pixel configured by the first subpixel SP1, the second subpixel SP2, and the third subpixel SP3. In an embodiment, the pixel may include a fourth sub-pixel SP4. The subpixels SP1, SP2, SP3, and SP4 are spaced apart and positioned adjacent to each other. As illustrated in FIG. 12A to 12D, the area between the subpixels SP1, SP2, SP3, and SP4 form a cross-shaped region.

The first subpixel SP1, the second subpixel SP2, and the third subpixel SP3 have different shapes, but have substantially same configuration.

For example, the first subpixels SP1 may be a red, green, or blue subpixel.

For example, the second subpixels SP2 may be a red, green, or blue subpixel.

For example, the third subpixels SP3 may be a red, green, or blue subpixel.

For example, the first subpixels SP1 and the third subpixel SP3 may have an approximately square shape, but the present disclosure is not limited thereto.

For example, the second subpixel SP2 may have an approximately rectangular shape, but is not limited thereto.

Here, a shape of the subpixels SP1, SP2, and SP3 may be defined by the shape of the anode, but it is not limited thereto.

In the meantime, according to the present disclosure, the anode has the SM structure so that a reflective emission area is added as well as the main emission area so that each emission area may be expanded as compared with each of the subpixels SP1, SP2, and SP3.

The p-doping layers 160a, 160b, 160c, and 160d of the exemplary embodiments of the present disclosure may be disposed in a border area between the subpixels SP1, SP2, and SP3.

The p-doping layer 160a of FIG. 12A is disposed along a region between the subpixels SP1, SP2, and SP3, but is not disposed in a portion which overlaps the border area. For example, the p-doping layer is disposed on the cross-shaped region between the adjacent subpixels, except for the intersection point of the cross-shaped region.

In this case, the anion generated in the black bank and the leakage current between the adjacent subpixels SP1, SP2, and SP3 may be effectively suppressed.

The p-doping layer 160b of FIG. 12B may be disposed only in a portion which overlaps the border area between the subpixels SP1, SP2, and SP3. For example, the p-doping layer is disposed on the intersection point of the cross-shaped region between the adjacent subpixels.

In this case, the anion generated in the black bank and the leakage current between the adjacent subpixels SP1, SP2, and SP3 may be suppressed, but the effect may be lower than that of the p-doping layer 160a of FIG. 12A.

The p-doping layer 160c of FIG. 12C may be disposed in a border area between the subpixels SP1, SP2, and SP3 including a portion which overlaps the border area. For example, the p-doping layer is disposed on the cross-shaped region between the adjacent subpixels.

In this case, the anion generated in the black bank and the leakage current between the adjacent subpixels SP1, SP2, and SP3 may be effectively suppressed.

Finally, the p-doping layer 160d of FIG. 12D may be disposed in the entire surface of the active area excluding the emission areas of the subpixels SP1, SP2, and SP3.

In this case, the anion generated in the black bank and the leakage current between the adjacent subpixels SP1, SP2, and SP3 may be suppressed, but the effect may be higher than that of the p-doping layer 160a of FIG. 12A.

In the meantime, the p-doping layer of the present disclosure is not applied only to the display device including the SM structure, which will be described in more detail with reference to the drawing.

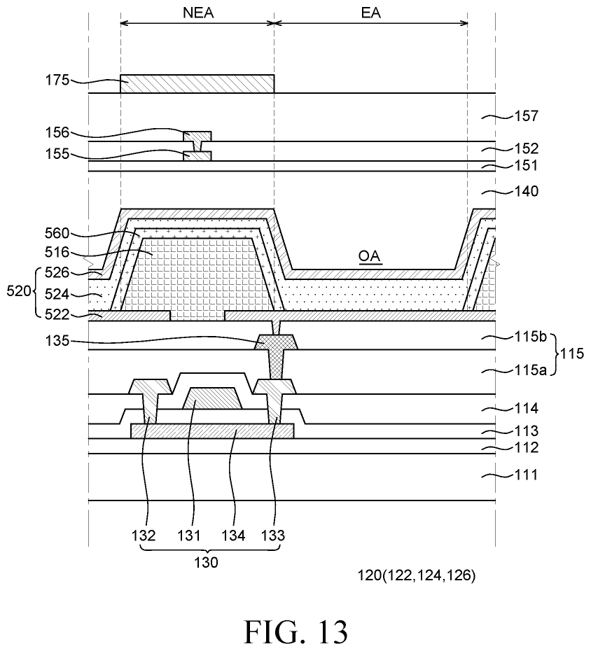

FIG. 13 is a view illustrating a part of a cross-section of a display panel according to a fifth exemplary embodiment of the present disclosure.

A fifth exemplary embodiment of the present disclosure of FIG. 13 has a different configuration of an anode 522 from that of the first exemplary embodiment of the present disclosure of FIGS. 4 and 5 described above, but other configurations are substantially the same so that a redundant description will be omitted.

For example, FIG. 13 illustrates a part of a cross-sectional structure of one subpixel of a display panel according to the fifth exemplary embodiment of the present disclosure.

Referring to FIG. 13, a planarization film 115 may be disposed above the substrate 111.

The anode 522 may be disposed above the planarization film 115.

At this time, for example, the anode 522 may be disposed on the second planarization film 115b to be in contact with the second planarization layer and a surface thereof may be substantially parallel to a surface of the substrate 111.

The anode 522 may include a reflective layer which is formed of a reflective metal.

A bank 516 may be disposed above the anode 522 and the second planarization film 115b.

For example, the bank 516 may be disposed in a non-emission area NEA of the substrate 111.

At this time, in the fifth exemplary embodiment of the present disclosure, when the bank 516 has a trapezoidal shape in which a lower side is wider than an upper side in a cross-sectional view, the first non-emission area NEA1 of the substrate 111 may be an area corresponding to the lower side of the bank 516.

The bank 516 may be formed of an organic material.

For example, the bank 516 may be formed of acrylic, polyimide, or benzocyclobutene-based resin, but is not limited thereto.

Further, the bank 516 may be formed of a black material.

For example, the bank 516 may be disposed so as to cover a part of the edge of the anode 522. The bank 516 may include an open area OA obtained by removing (opening) a part corresponding to the emission area EA of a subpixel.

A doping layer 560 may be disposed on a top surface and a side portion of the bank 516.

For example, the doping layer 560 may be disposed on the top surface and the side portion of the bank 516 so as to cover the bank 516.

For example, the doping layer 560 may be a p-doping layer 560 which is formed by injecting a p-type impurity to have a cationic property.

The organic layer 524 may be disposed on the top surface and a side portion of the bank 516 and the doping layer 560 including the open area OA of the bank 516.

Further, the cathode 526 may be disposed on the entire surface of the substrate 111 on which the organic layer 524 is disposed.

An encapsulation unit 140 may be disposed above the cathode 526.

A touch panel including a touch buffer film 151, a bridge pattern 155, a touch insulating film 152, and a touch electrode (or, a touch line) 156 may be disposed above the encapsulation unit 140.

The planarization film 157 and the black matrix 175 may be disposed above the touch panel.

The black matrix 175 may be disposed so as to correspond to the bottom surface of the bank 516.

The black matrix 175 may have a width corresponding to the bottom surface of the bank 516.

The exemplary embodiments of the present disclosure can also be described as follows:

According to an aspect of the present disclosure, there is provided a display device. The display device comprises a planarization layer disposed above a substrate, a first bank disposed on the planarization layer, an anode disposed on the planarization layer and on a side surface of the first bank, a second bank covering a portion of the anode and the first bank and disposed above the first bank and the anode, a doping layer disposed on a top surface and a side portion of the second bank, an organic layer which is disposed on the doping layer and the anode, a cathode disposed on the organic layer and an encapsulation unit disposed above the cathode.

According to another aspect of the present disclosure, there is provided a display device. The display device comprises a planarization layer disposed above a substrate, a first bank disposed on the planarization layer, an anode disposed on the planarization layer and on a side surface of the first bank, a second bank covering a portion of the anode and the first bank and disposed above the first bank and the anode, an organic layer disposed on the second bank and the anode, a cathode disposed on the organic layer and an encapsulating unit disposed above the cathode, the second bank may include a p-type impurity with a positive charge.

The first bank may be configured by a black material and the second bank may be configured by a transparent material.

The first bank may include a top surface, a bottom surface, and a side surface.

The anode may include a first area which is disposed on the planarization film to be in contact with the planarization film, a second area which extends from the first area to be disposed on a side surface of the first bank and has a surface having a predetermined angle with respect to the substrate and a third area which extends from the second area to be in contact with the top surface of the first bank.

The second area of the anode may be disposed on a side surface of the first bank along a shape of the side surface of the first bank.

The second bank may be disposed to cover a part of an edge of the first area and the second area and the third area.

The second bank may include a top surface which is located at the top of the second bank and corresponds to a top surface of the first bank, a side portion which extends from the top surface of the second bank to the side surface and corresponds to the side surface of the first bank and a bottom surface in contact with the anode in the first area of the anode.

The doping layer may be disposed on the top surface and the side portion of the second bank to cover the second bank.

The doping layer may be a p-doping layer in which a p-type impurity is injected.

The p-type impurity may include boron (B), indium (In), or gallium (Ga).

The substrate may be divided into a first area corresponding to a main emission area and a second area other than the first area, and the first bank, the second bank, and the doping layer may be disposed only in the second area.

The organic layer may include a p-hole injection layer which is disposed in the first area and the second area, a hole transport layer disposed on the p-hole injection layer, an emission layer disposed on a hole transport layer of the first area and an electron transport layer disposed in the first area and the second area, and the doping layer may have a doping concentration higher than the p-hole injection layer.

The doping layer may extend to the first area of the anode.

The substrate may be divided into a first area corresponding to a main emission area and a second area other than the first area, and the first bank and the second bank may be disposed only in the second area, and the doping layer may have a thickness in the second area larger than that in the first area.

The organic layer may include a p-hole injection layer which is disposed in the first area and the second area, a hole transport layer disposed on the p-hole injection layer, an emission layer disposed on a hole transport layer of the first area and an electron transport layer disposed in the first area and the second area, and the doping layer may have a doping concentration higher than the p-hole injection layer, and a doping layer of the second area may have a thickness larger than that of the p-hole injection layer.

The second bank may be configured by a first-second bank and a second-second bank, and the doping layer may be disposed between the first-second bank and the second-second bank.

The first bank may be configured by a black material and the second bank may be configured by a transparent material.

The doping layer may be a p-doping layer in which a p-type impurity is injected.

The p-type impurity may include boron (B), indium (In), or gallium (Ga).

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a planarization layer disposed above a substrate;
a first bank disposed on the planarization layer;
an anode disposed on the planarization layer, the anode disposed on a side surface of the first bank;
a second bank covering a portion of the anode and the first bank, the second bank disposed above the first bank and the anode;
a doping layer disposed on a top surface and a side portion of the second bank;
an organic layer which is disposed on the doping layer and the anode;
a cathode disposed on the organic layer; and
an encapsulation unit disposed above the cathode.

2. The display device according to claim 1, wherein the first bank is configured by a black material and the second bank is configured by a transparent material.

3. The display device according to claim 1, wherein the doping layer is disposed on the top surface and the side portion of the second bank to cover the second bank.

4. The display device according to claim 1, wherein the doping layer is a p-doping layer in which a p-type impurity is injected.

5. The display device according to claim 1, wherein the substrate is divided into a first area corresponding to a main emission area and a second area other than the first area, and the first bank, the second bank, and the doping layer are disposed only in the second area.

6. The display device according to claim 5, wherein the organic layer includes:
a p-hole injection layer which is disposed in the first area and the second area;
a hole transport layer disposed on the p-hole injection layer;
an emission layer disposed on the hole transport layer of the first area; and
an electron transport layer disposed in the first area and the second area, and
wherein the doping layer has a doping concentration higher than the p-hole injection layer.

7. The display device according to claim 1, wherein the second bank is configured by a first-second bank and a second-second bank, and the doping layer is disposed between the first-second bank and the second-second bank.

8. The display device according to claim 7, wherein the first bank is configured by a black material and the second bank is configured by a transparent material.

9. The display device according to claim 7, wherein the doping layer is a p-doping layer in which a p-type impurity is injected, wherein the p-type impurity includes boron (B), indium (In), or gallium (Ga).

10. A display device, comprising:
a planarization layer disposed above a substrate;
a first bank disposed on the planarization layer;
an anode disposed on the planarization layer, and on a side surface of the first bank;
a second bank covering a portion of the anode and the first bank and disposed above the first bank and the anode;
an organic layer disposed on the second bank and the anode;
a cathode disposed on the organic layer, and
an encapsulating unit disposed above the cathode, wherein the second bank includes a p-type impurity with a positive charge.

11. The display device according to claim 10, wherein the first bank is configured by a black material and the second bank is configured by a transparent material.

12. The display device according to claim 10, wherein the anode includes:
a first area which is disposed on a planarization film to be in contact with the planarization film;
a second area which extends from the first area to be disposed on the side surface of the first bank and has a surface having a predetermined angle with respect to the substrate; and
a third area which extends from the second area to be in contact with a top surface of the first bank.

13. The display device according to claim 12, wherein the second area of the anode is disposed on a side surface of the first bank along a shape of the side surface of the first bank.

14. The display device according to claim 12, wherein the second bank is disposed to cover a part of an edge of the first area and the second area and the third area.

15. The display device according to claim 12, wherein the second bank includes:
a top surface which is located at a top of the second bank and corresponds to a top surface of the first bank;
a side portion which extends from the top surface of the second bank to the side surface and corresponds to the side surface of the first bank; and
a bottom surface in contact with the anode in the first area of the anode.

16. The display device according to claim 15, wherein the p-type impurity includes boron (B), indium (In), or gallium (Ga).

17. The display device according to claim 12, wherein a doping layer extends to the first area of the anode.

18. The display device according to claim 17, wherein the substrate is divided into a first area corresponding to a main emission area and a second area other than the first area, and the first bank and the second bank are disposed only in the second area, and the doping layer has a thickness in the second area larger than that in the first area.

19. The display device according to claim 18, wherein the organic layer includes:
a p-hole injection layer which is disposed in the first area and the second area;
a hole transport layer disposed on the p-hole injection layer;
an emission layer disposed on a hole transport layer of the first area; and
an electron transport layer disposed in the first area and the second area, and
wherein the doping layer has a doping concentration higher than the p-hole injection layer, and a doping layer of the second area has a thickness larger than that of the p-hole injection layer.

20. A display device, further comprising:
a substrate;
a planarization layer disposed on the substrate;
a first subpixel and a second subpixel on the substrate, the second subpixel spaced apart from and positioned adjacent to the first subpixel, and each of the first subpixel and second subpixel including:
an anode electrode, the anode electrode including reflective material;
at least a portion of an organic layer; and
at least a part of a cathode electrode on the organic layer;
a first black bank between the first subpixel and the second subpixel, wherein the anode electrode extends to a side surface of the first black bank; and
a doping layer disposed above the first black bank.

21. The display device of claim 20, wherein the anode electrode extends to have an end disposed on a top surface of the first black bank.

22. The display device of claim 20, further comprising a second bank between the doping layer and the first black bank.

23. The display device of claim 22, wherein the doping layer extends to an emission area of the first subpixel, and is disposed between the anode electrode and the portion of the organic layer.

24. The display device of claim 22, wherein the doping layer is the second bank, and the second bank includes dopants.

25. The display device of claim 20, further comprising:
a third subpixel and a fourth subpixel on the substrate, the fourth subpixel spaced apart from the third subpixel and is positioned adjacent to the third subpixel, each of the third subpixel and the fourth subpixel including:
the anode electrode, the anode electrode including reflective material;
at least a portion of the organic layer, and
at least a part of the cathode electrode on the organic layer; wherein the third subpixel and fourth subpixel are spaced apart from and positioned adjacent to the first subpixel and second subpixel, forming a cross-shaped region between the first subpixel, the second subpixel, the third subpixel, and the fourth subpixel.

26. The display device of claim 25, wherein the doping layer is disposed on the cross-shaped region.

27. The display device of claim 25, wherein the doping layer is disposed on an intersection point of the cross-shaped region.
